(19) United States
(12) Patent Application Publication
(10) Pub. No.: US 2024/0355884 A1
(43) Pub. Date: Oct. 24, 2024

(54) PURIFIED SURFACE REGION OF AN OXIDE SEMICONDUCTOR, AND METHOD OF NEAR-SURFACE PURIFICATION

(71) Applicant: The Board of Trustees of the University of Illinois, Urbana, IL (US)

(72) Inventor: Edmund G. Seebauer, Urbana, IL (US)

(73) Assignee: The Board of Trustees of the University of Illinois, Urbana, IL (US)

(21) Appl. No.: 18/639,102

(22) Filed: Apr. 18, 2024

Related U.S. Application Data
(60) Provisional application No. 63/460,505, filed on Apr. 19, 2023.

(51) Int. Cl. H01L 29/08; H01L 21/02; H01L 21/225

(52) U.S. Cl. CPC H01L 29/0878; H01L 21/02334; H01L 21/2253; H01L 29/086

(57) ABSTRACT

A purified surface region of a semiconductor includes a treated surface and comprises a crystalline metal oxide containing an impurity species (e.g., an isotopic impurity or a chemical impurity). The crystalline metal oxide comprises a depletion region extending to a first depth from the treated surface, and an accumulation region adjacent to the depletion region and extending to a second depth greater than the first depth. A concentration of the impurity species is lower in the depletion region than in the accumulation region. An electronic component comprising the purified surface region may be used for thermal management, quantum computing, sensing, and/or light detection.

### RELATED APPLICATION

The present patent document claims the benefit of priority under 35 U.S.C. 119 (e) to U.S. Provisional Patent Application No. 63/460,505, which was filed on Apr. 19, 2023, and is hereby incorporated by reference in its entirety.

### FEDERALLY SPONSORED RESEARCH AND DEVELOPMENT

This invention was made with government support under DMR 1709327 awarded by the National Science Foundation. The United States Government has certain rights in the invention.

### TECHNICAL FIELD

The present disclosure is related generally to purification of semiconductors and more particularly to surface-enhanced solid-state diffusion in oxide semiconductors to achieve near-surface purification.

### BACKGROUND

Isotopically pure semiconductors may have important applications for cooling electronic devices and for quantum computing and sensing. Faster thermal conduction augments device cooling. In quantum devices, spinning nuclei require isolation from environmental perturbation by isotopically pure layers having nuclear spins of zero. Raw materials of sufficiently high isotopic purity are expensive and difficult to obtain, so a post-synthesis method for removing isotopic impurities would be valuable. It would also be beneficial to develop methods for removing chemical impurities from semiconductor surfaces for electronic and optoelectronic applications that may require high material purities.

### BRIEF DESCRIPTION OF THE DRAWINGS

FIG. 1A is a schematic of a surface region of a semiconductor showing injection of atomic oxygen and creation of an interstitial.

FIG. 1B is a schematic of a surface region of a semiconductor showing injection of a metal cation and creation of an interstitial.

FIGS. 2A and 2B are ¹⁸O diffusion (or concentration) profiles showing deep penetration and isotopic fractionation for various bias voltages (Vₐₚₚₗ) and temperatures (T) for an injection time (or water exposure duration) of one hour.

FIG. 2C is an ¹⁸O diffusion profile showing that isotopic fractionation, or the “snowplow effect,” arises even in response to injection of (only) natural abundance atomic oxygen (¹⁶O) for an injection time of one hour at 70° C.

FIG. 3A is a schematic of a surface region of a semiconductor showing injection of one or more heteroatoms and creation of interstitials.

FIG. 3B is a schematic of a surface region of a semiconductor showing injection of an atomic species and creation of an interstitial, leading to annihilation of a vacancy.

FIG. 4 illustrates interstitialcy diffusion, whereby any individual atom is left in the lattice after about 2 hops, after which there is only a ¼ chance for continued hopping.

FIG. 5 shows room temperature diffusion profiles for manganese (Mn) in TiO₂, where penetration occurs for both positive and negative biases vs Ag/AgCl.

FIG. 6 plots ¹⁸O diffusion profiles showing isotopic fractionation for various bias voltages with and without ultraviolet (UV) irradiation at 70° C. for an injection time of one hour.

FIGS. 7A and 7B show exemplary ¹⁸O diffusion profiles for TiO₂(110) immersed in water at various temperatures for 1 hour at pH levels of 5 and 9, respectively.

FIG. 8A shows exemplary ¹⁸O diffusion profiles for TiO₂(110) immersed in water at various temperatures for 1 hour at pH 7.

FIG. 8B compares the 70° C. profile from FIG. 8A with the salt (Na and Cl) added profile (pH 7). The salt-free 70° C. profiles in each figure are actually two different scans of the same sample.

FIGS. 9A and 9B show Arrhenius plots for valley width and net injection flux (F₁₈), respectively, for TiO₂(110) comparing conditions at pH levels 5 and 9. Dashed lines represent linear least squares fits, and each point represents the average of profiles taken at three different locations on a specimen's surface, typically for 2-4 distinct specimens. Confidence intervals were computed for all points; where no bars are visible, the range is smaller than the size of the data point.

FIGS. 10A-10C show exemplary ¹⁸O diffusion profiles for 1 hour at pH 7 at a temperature of 40° C., 50° C., and 60° C., respectively. Red and blue curves compare specimens having treated surfaces prepared by room-temperature wet etching (red) and high-temperature annealing in O₂. It is believed that annealing removes trapping sites for Oᵢ, and leads to gradients in Oᵢ concentration that are less sharp. The near-surface isotopic fractionation is correspondingly smaller.

### DETAILED DESCRIPTION

A new method for achieving isotopic and/or chemical purification in near-surface regions of oxide semiconductors has been developed. The approach involves efficient and controllable injection of interstitial atoms into semiconducting metal oxides from treated surfaces exposed to aqueous liquids (e.g., water). By operating near room temperature, it is possible to access a regime wherein concentrations of native defects normally become vanishingly small, and where kinetic rather than thermodynamic effects may dominate defect behavior. Post-synthesis removal of low-concentration isotopic or chemical impurities from semiconducting metal oxides may be beneficial for various applications. For example, elimination of chemical impurities near surfaces can improve the performance of solar photocathodes and other electronic devices, and elimination of isotopic impurities may provide semiconductors tailored for applications in thermal management, quantum computing and sensing.

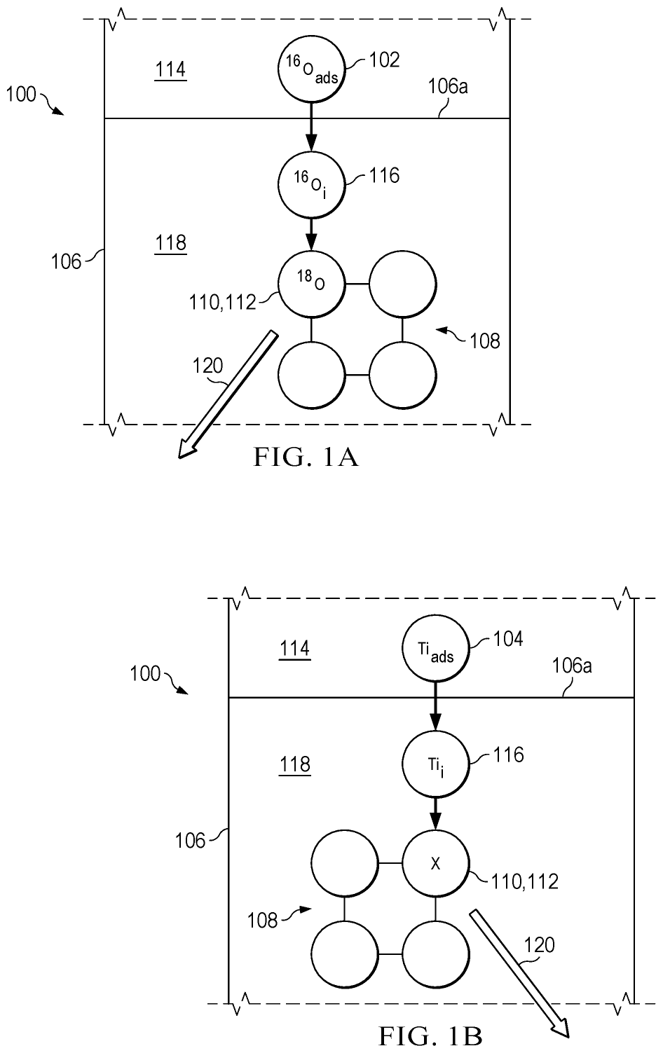

Referring to FIGS. 1A and 1B, the method includes injecting atomic oxygen 102 or metal cations 104 into a treated surface 106a of a semiconductor 106 comprising a crystalline metal oxide 108 and an impurity species 110, which may be an isotopic impurity 112 (e.g., an oxygen isotope such as ¹⁸O or a host metal isotope X) or a chemical impurity. It is understood that the impurity species is an atomic species deemed to be undesirable or unwanted in the crystalline metal oxide, possibly depending on the intended application of the semiconductor. Injection may be achieved by submerging the treated surface 106a in water or an aqueous solution 114, whereby a portion of the water 114 adsorbs onto the treated surface 106a and dissociates into atomic oxygen 102, as illustrated in FIG. 1A, and hydrogen. (Beneficially, dissociation of the water 114 on the treated surface 106a does not lead to incorporation of hydrogen, which is typically an unwanted species, into the crystalline metal oxide 108.) When metal cations 104 are injected, as in FIG. 1B, the aqueous solution 114 may contain a soluble compound comprising the metal cations 104, which adsorb onto the treated surface 106a while the treated surface is submerged or otherwise exposed to the water/aqueous solution 114. Exemplary metal cations 104 may include Ti, Zn, Ga, Sr, Sn, In, W, Cr, Cu and/or Co.

Injection of the atomic oxygen 102 and/or metal cations 104 into the treated surface 106a is believed to create mobile detect species 116 comprising interstitial atoms. For example, referring to FIG. 1A, the mobile defect species 116 may comprise oxygen interstitials (Oᵢ), rather than oxygen vacancies (Vₒ) or another oxygen-containing complex. (The terms “oxygen interstitials,” “interstitial oxygen,” and “Oᵢ” are used interchangeably throughout this disclosure.) In examples where metal cations 104 are injected, as in FIG. 1B, the injected mobile species 116 may comprise metal interstitials (e.g., Tiᵢ, as in this example). Control over the pH of the water or aqueous solution 114, application of an electrochemical bias, and/or exposure to above-bandgap radiation may influence adsorption and injection, as discussed further below.

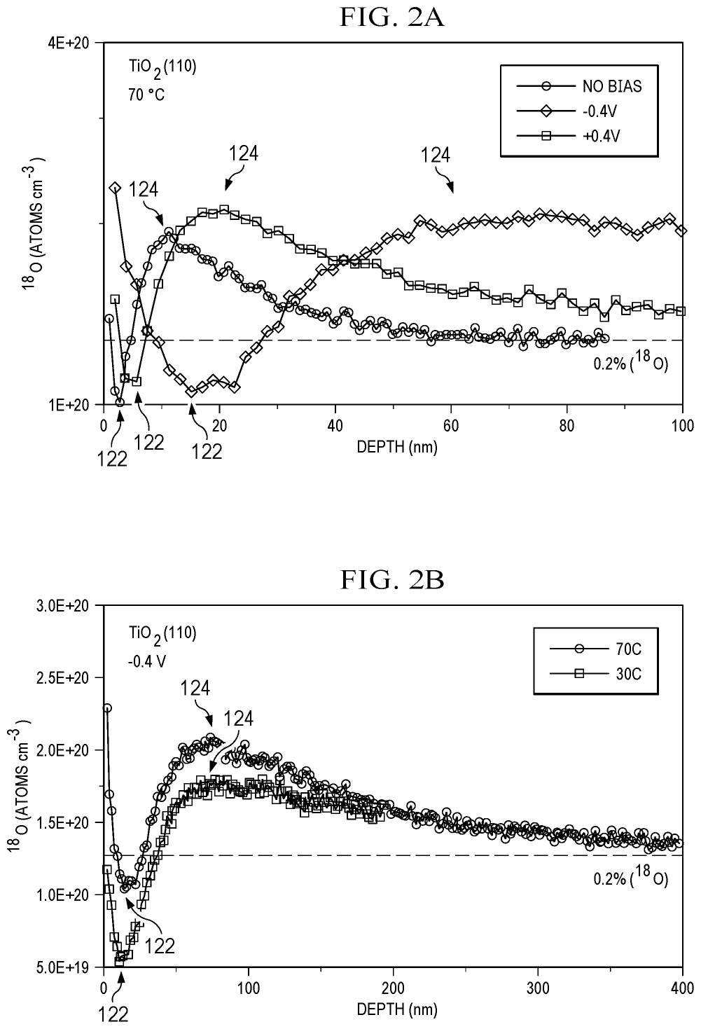

Accordingly, once injected, the atomic oxygen 102 or metal cations 104 move through the crystalline metal oxide 108 as interstitials 116, as illustrated in FIGS. 1A and 1B, via interstitialcy-mediated diffusion. Consequently, impurity species 110 are depleted from a (near-surface) depletion region 118 of the semiconductor 106 and diffused deeper into the crystalline metal oxide 108 to an accumulation region 120, which is farther from the treated surface 106a than the depletion region 118. This fractionation or near-surface purification may be referred to as a “snowplow effect” given the shape of diffusion (or concentration) profiles of the impurity species, and the fact that impurity atoms are selectively displaced from the near-surface region to a location deeper in the solid. This can be seen for example in FIGS. 2A and 2B, which show ¹⁸O diffusion profiles obtained after exposure of a treated surface 106a of TiO₂(110) to water under various conditions of applied voltage and temperature, as indicated in the plots. The impurity species 110 (¹⁸O in this example) is effectively “snowplowed” deeper into the metal oxide 108 due to a large interstitial gradient and a statistical bias against diffusion of impurity atoms 110, as explained below. Counterintuitively, the isotopically depleted valleys 122 evident in the concentration profiles of FIGS. 2A and 2B emerge despite enrichment of the liquid water 114 with the isotopic impurity 112, specifically, with 10% ¹⁸O in these examples. The ¹⁸O concentration of the near-surface depletion region 118 (shown schematically in FIG. 1A) drops by as much as a factor of three below the natural abundance level, which is represented by the dotted horizontal lines in the figures, and the ¹⁸O lost from the valley 122 builds up as a peak 124 in the accumulation region. FIG. 2C shows that the snowplow effect arises even in response to injection of (only) natural abundance atomic oxygen (¹⁶O), suggesting that the isotopic or chemical identity of the injecting interstitials is not limited to a particular species. Generally speaking, the injected species may have chemical properties that allow it to substitute into the crystalline metal oxide in place of the impurity species and also to diffuse via a mechanism mediated by interstitials, preferably with appreciable mobility at the temperature of interest.

The snowplow effect may require both a large interstitial gradient and a large statistical bias against diffusion of the impurity species compared to the corresponding host. As indicated above, the impurity may be isotopic in nature, such as a minority oxygen isotope. When a treated surface 106a of a semiconductor 106 comprising a crystalline metal oxide 108 contacts (e.g., is submerged in) an aqueous solution or water 114, as illustrated in FIG. 1A, sizable fluxes of Oᵢ 116 may be generated in the crystalline metal oxide 108. Since the equilibrium concentration of Oᵢ at or near room temperature is extremely small, large injected fluxes of Oᵢ can produce large concentration gradients. In addition, the isotopes mobilized as interstitials from the local lattice may exhibit strong differences in mesoscale diffusivities due to statistical bias, as explained below, so that the majority isotope (e.g., ¹⁶Oᵢ) races far ahead of the isotopic impurity or minority isotope (e.g., ¹⁸Oᵢ). When the gradient in the interstitial concentration is high, the leading edge of the diffusion “front” of interstitials has a strong compositional bias toward the majority isotope. Over many cycles of lattice sequestration and release, this statistical bias “snowplows” the minority isotope, creating the characteristic valley-and-peak shape seen in FIGS. 2A-2C. It has been observed that smaller gradients in interstitial concentration from smaller injection rates may enable random-walk diffusion to smooth out the snowplow effect—to the point of invisibility in some cases, e.g., in the absence of an electrochemical bias and/or in gas exchange at high temperatures.

While the diffusion profiles of FIGS. 2A-2C show isotopic oxygen, it is emphasized that the near-surface purification method is not limited to atomic oxygen, nor to host anions. The method is applicable to minority isotopes of any host anion or cation that can diffuse by a mechanism mediated by interstitials, assuming a sharp gradient in interstitial concentration can be generated in a semiconductor having large disparities in isotopic concentration. Indeed, the method is also applicable to extrinsic atoms that can diffuse by a mechanism mediated by interstitials. (It is understood that a host anion or host cation has the elemental composition of the anionic or cationic component, respectively, of the crystalline metal oxide, whereas an extrinsic atom or heteroatom has a different elemental composition than the components of the crystalline metal oxide.) Host cations in many metal oxides diffuse by mechanisms mediated by interstitials and may have minority isotope concentrations below about 3%, including Cr (2.4%), Zn (0.6%), Sn (0.34%), Zr (2.8%), Hf (0.16%), and the rare earths La (0.09%), Ce (0.19%), Gd (0.2%), Yb (0.12%), and Dy (0.056%). In the example of TiO₂, the Ti cation diffuses by an interstitialcy mechanism along the [110] direction. For the highest isotopic purity with little buildup of unwanted isotopes near the treated surface, it is advisable to use a source of interstitial atoms that is enriched in the desired isotope (i.e., the isotopic impurity). However, as indicated above, data show that snowplow effects arise even in response to injection of majority isotopes, suggesting that the isotopic composition of the injecting interstitials is not critical to the existence of snowplow effects.

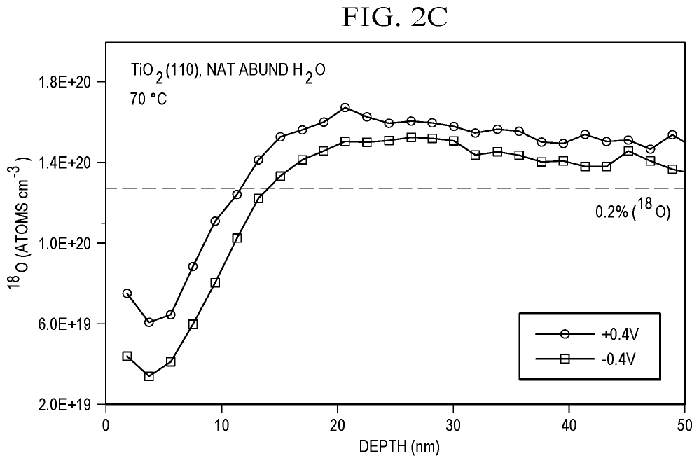

Referring to FIG. 3A, a snowplow effect may be observed for injecting heteroatoms (X_{ads}, Y_{ads}) that diffuse by a mechanism mediated by interstitials (Xᵢ, Yᵢ), and could also affect small pre-existing concentrations of such heteroatoms in the bulk. Indeed, statistical biases in mesoscale dopant diffusion have been reported for dopants in silicon that diffuse by an interstitial mechanism for which the mean diffusion length before kick-in is short. The method described in this disclosure may be employed for removing unwanted chemical impurities (e.g., impurity metal cations) from surfaces and, if desired, the method may further may allow for doping with desired metal cations. Low temperature dopant introduction by controllable injection of cation interstitials may provide a better alternative to existing post-synthesis semiconductor doping methods. The low temperature and highly non-equilibrium conditions may enable the circumvention of thermodynamic considerations, and many metal ions are readily soluble in water. Diffusion in the solid often takes place by interstitial-type mechanisms with barriers well below 1 eV. Purification of metal oxide semiconductors to remove unwanted metal cations, optionally followed by heteroatom doping, may have applications in sensors, electronics and optoelectronics, spintronics, catalysis (including photocatalysis and electrocatalysis) and energy storage.

The approach described in this disclosure may also be useful for defect engineering. As illustrated in FIG. 3B, the diffusing interstitials (Xᵢ) may replace or “annihilate” vacancies (V) in the crystalline metal oxide. For example, the crystalline metal oxide may include an oxygen vacancy concentration on the order of 1×10¹⁶ cm⁻³ prior to the method, and all or substantially all (e.g., greater than 99%) of the oxygen vacancies (Vₒ) over a predetermined depth may be annihilated by the oxygen interstitials, such that Oᵢ becomes the majority oxygen-related native point defect. It has been demonstrated in several oxides that injection of Oᵢ near room temperature can eliminate Vₒ to depths extending to the micron level. The presence of vacancies in semiconducting metal oxides may be detrimental in some applications, such as renewable energy production and storage, photocatalysis, photoelectrochemistry, and electronics.

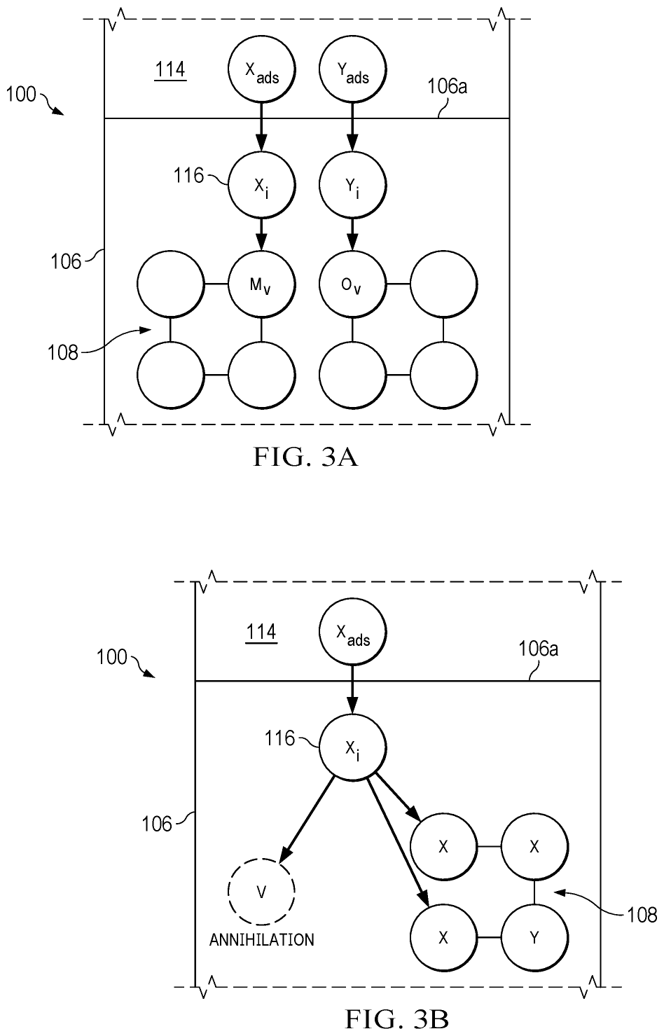

The statistical bias referred to above, which may produce large disparities in isotopic diffusivity, may stem from typical interstitial geometries, where two atoms lie symmetrically around the original position of a normal lattice atom. The high symmetry implies that either O atom within the interstitial hops with equal probability. Thus, any particular atom (host ¹⁶O or “impurity” ¹⁸O) finding itself within an interstitial can execute only 2-3 hops on average before becoming temporarily immobilized in the lattice. For example, the likelihood of a given atom surviving in a mobile state after two hops is 0.5²=0.25. Remaining mobile after three hops has a likelihood of only 0.5³=0.125. As FIG. 4 illustrates, such statistics govern the immobilization of any atom regardless of whether it is labeled. However, each hop conserves the interstitial as a chemical species; only the constituent atoms change. For dilute impurity concentrations, the lattice consists almost entirely of host. Thus, immobilization of impurity usually mobilizes a host atom. However, immobilization of a host atom usually releases another host. Indeed, a host interstitial traverses the solid for many atomic diameters before finally liberating an impurity atom. Only rarely can immobilization of impurity release another impurity. In the case of a minority isotope (such as ¹⁸O), these statistics may lead to an effective diffusivity that differs from the hopping diffusivity Dₕₒₚ of a hypothetical single-isotope solid by factor of [¹⁸Oᵢ]/([¹⁸Oᵢ]+[¹⁶Oᵢ]). For very dilute impurities, the statistical factor may scale the effective diffusivity by several orders of magnitude. No equivalent effect occurs for a vacancy mechanism. This interstitialcy mechanism, which entails frequent exchange between atoms in the defect and on lattice sites, may be distinguished from an interstitial mechanism wherein a single interstitial atom diffuses many lattice spacings before becoming trapped or kicking into the lattice. However, it is believed that an analogous effect operates in modified form for interstitialcy diffusion of extrinsic chemical elements and for interstitial diffusion of either isotopes or extrinsic chemical elements where the mean diffusion length before kick-in to the lattice is short (e.g., a few lattice spacings).

It is noted that the activation energy or injection barrier for the incorporation of oxygen interstitials into a treated surface of a semiconducting metal oxide, such as TiO₂, ZnO or Ga₂O₃, is found to lie only 0.1-0.2 eV above the lattice site-hopping barrier, which itself is 1 eV or less. These values allow for technologically useful injection rates near room temperature. For example, the lattice site-hopping barriers for Oᵢ in a-axis ZnO and TiO₂ are about 0.6 eV and 0.9 eV, respectively. It is believed that small injection barriers may be found for a wide variety of metal oxides. Hopping barriers of 1 eV or less together with injection barriers exceeding the hopping barriers only slightly may enable diffusion lengths of tens to thousands of nanometers at only a few tens of degrees above room temperature (e.g., 30° C. to <100° C.). It is believed that significant incorporation of interstitial oxygen can occur in this temperature range if the water exposure yields adsorbed oxygen and if co-adsorbates do not poison incorporation sites or raise the injection barrier. Generally speaking, the activation energy or injection barrier appears to be influenced by the type of metal oxide, presence of neighboring adsorbates, charge state of the O defect, and surface reconstruction. The depth of Oᵢ penetration may depend on the type of metal oxide, charge state of the oxygen defect, and/or the concentration of sequestration sites, as well as how strongly the Oᵢ bonds to these sites.

Injection of the atomic oxygen or metal cations may take place at a temperature and pressure sufficient to maintain the water in a liquid phase; for example, the temperature may be less than 100° C. (e.g., at or near room temperature (20-25° C.), or in a range from 30-80° C.) and the pressure may be atmospheric pressure. Alternatively, the temperature may be at or above 100° C. and the pressure may be in a range from greater than about 100 kPa to about 10 GPa. The aqueous solution may include a metal salt (e.g., to provide the metal cations for adsorption and/or to make the aqueous solution electrically conductive for an electrochemical bias, as discussed below). Also or alternatively, the aqueous solution may include an acid and/or a base, e.g., to control pH, which may lie in a range from 2 to 10. The selected pH may depend on the particular chemistry involved with the goal of enhancing the injection rate. For example, a basic pH may help transform adsorbed OH to injectable O. On the other hand, some dissolved salts, such as TiCl₃, may require a pH far from 7 (e.g., strong acid, pH=2 to 4) to avoid side precipitation reactions.

Injection of the atomic oxygen or metal cations may be enhanced by applying a bias voltage while the treated surface is submerged in the aqueous solution or water. An electrochemical cell may be set up which includes working and counter electrodes and optionally a reference electrode in contact with the aqueous solution and electrically connected to a power supply. It has been demonstrated that application of a bias voltage promotes complete water dissociation (i.e., removal of both H atoms) to inject Oᵢ. Also or alternatively, application of a bias voltage can promote surface redox reactions that create injectable metal atoms on the surface from metal cations dissolved in the liquid (water or aqueous solution). Indeed, electrochemical biases greatly enhance the rate of redox reactions for creating injectable O, suggesting that similar phenomena could occur for metal cations and other anions such as sulfur (S) or nitrogen (N).

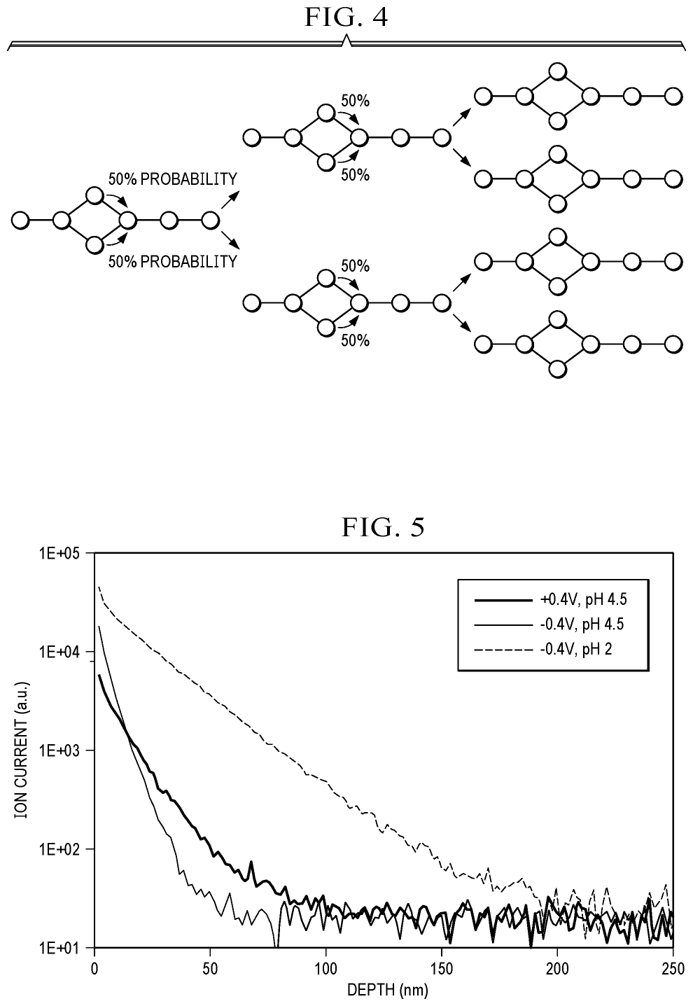

The electrochemical bias may be positive or negative; both positive and negative applied biases Vₐₚₚₗ have been shown to be effective, as evidenced in FIGS. 2A and 2C. Under some conditions, the profiles extend to 400 nm after an hour—strikingly deep considering that the experiments were done in a range of very modest temperatures: 30-70° C. An electrochemical bias may increase the net injection flux Fₒ and/or the mean diffusion length λₒ of the interstitial species by over an order of magnitude-comparable to gas-phase numbers seen at temperatures 600-700° C. hotter. FIG. 5 shows room temperature diffusion profiles for manganese (Mn) in TiO₂, wherein penetration occurs for both positive and negative biases vs Ag/AgCl. Penetration depths range up to 200 nm, and maximum ion currents near the surface lie only about an order of magnitude of those for Ti (sum of isotopes). The bias threshold for enhancement is only about ±0.1 V vs Ag/AgCl. Preferably, the applied bias Vₐₚₚₗ lies in a range from −0.6 V to +0.6 V vs Ag/AgCl.

It is noted that these effects relate only distantly to the well-known phenomenon of ionic conduction. In most oxides exhibiting ionic conduction including TiO₂, diffusion of vacancies (Vₒ) dominates the ion flux. Current flow occurs by thermally activated hopping of ions, with a superimposed drift driven by the electric field. The ionic conductivity exhibits a strong dependence on temperature (T) and occurs above at least 350° C., and more commonly above 600° C. By contrast, the injection method described herein exhibits a weak temperature dependence, occurs with similar magnitude regardless of the electric field's direction, and operates even at room temperature. Notably, control experiments omitting pretreatment to remove surface poisons lead to much less penetration of the isotopic impurity.

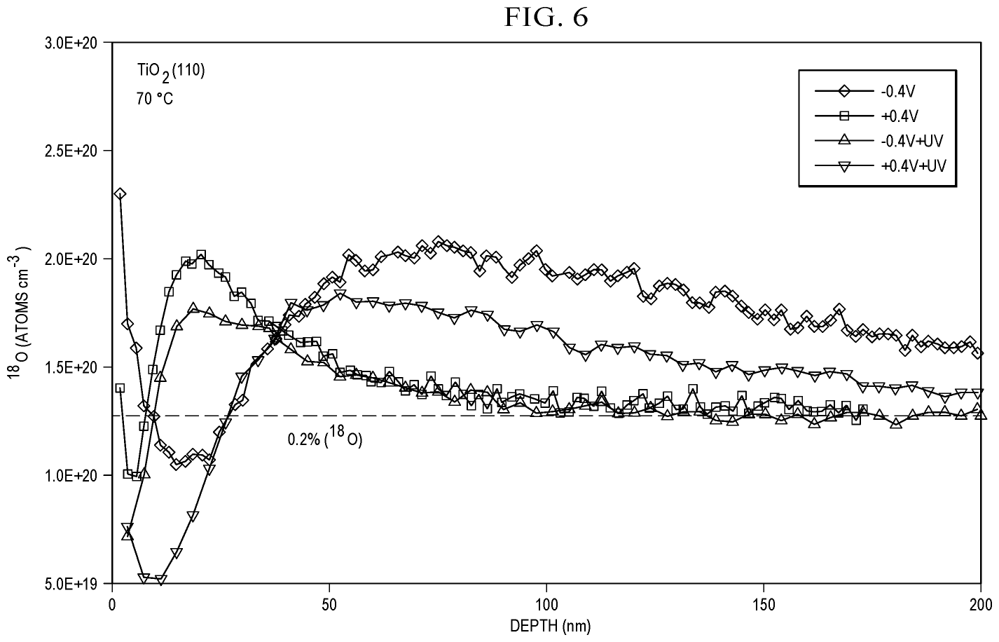

Injection of the atomic oxygen or metal cations may be enhanced by illuminating the treated surface 106a shown schematically in FIGS. 1A and 1B with ultraviolet light or, more generally speaking, radiation having a photon energy at or above the bandgap of the semiconductor 106, while the treated surface 106a is exposed to the gas or liquid (aqueous solution or water 114). Such radiation may be referred to as “above-gap” or “super-bandgap” radiation. Experiments have shown UV-enhanced injection of Oᵢ from rutile TiO₂(110) surfaces exposed to water at Vₐₚₚₗ=0. The data shown in FIG. 6 reveal that these effects extend to Oᵢ injection with an applied bias. The effects are complicated, but the data suggest that illumination with ultraviolet light, or with light having a wavelength corresponding to a photon energy at or above the bandgap of the semiconductor (TiO₂, in this example), inhibits injection for Vₐₚₚₗ<0 and enhances injection for Vₐₚₚₗ>0.

Photostimulated changes in diffusion behavior relies upon a Fermi energy dependence of the charge state for the diffusing interstitial or one of its trapping complexes. Whether such charge states vary under illumination depends upon the light intensity, minority carrier lifetime, kinetics of electron and hole interaction with the interstitial or complex, and numerous other factors. However, such effects may occur at low light intensities far more readily at room temperature than at elevated temperatures because thermionic emission of minority carriers (which swamps photogeneration) increases exponentially with temperature. Interstitial diffusivities in semiconductors commonly vary with charge state. UV stimulation may therefore manifest as variations in isotopic penetration in the deep bulk. Additional drift effects may appear in a surface charge layer (SCL), and changes in charge state may manifest as a spatial dependence in the trapping of interstitials within the SCL.

Repeated cycles (e.g., 2 or more, and as many as 20) of interstitial injection may lead to improved isotopic or chemical purity. As the interstitials penetrate the bulk diffusively over time, their gradients become less sharp. Smaller interstitial gradients enable random diffusion to smooth out and perhaps eliminate the valley. Pausing the injection at intervals, that is, temporarily halting the exposure of the treated surface to water or an aqueous solution, enables the injected interstitials to disperse and sequester in trap sites at modest temperatures (e.g., 20° C. to 70° C.), where equilibrium interstitial concentrations are low. Successive cycles of injection (re-exposure to the water/aqueous solution) may generate fresh waves of interstitials that re-establish sharp gradients. It is inherent in the statistical aspects of solid-state impurity purification that the difference in effective diffusivity between host and impurity becomes larger as the impurity concentration decreases. In other words, the purification process works better as the material becomes purer. Such behavior is very rare for any kind of separation process.

It has been recognized that several principles govern interstitial injection. First, injectable atoms are preferably bonded only to a treated surface, that is, a clean (unpoisoned) surface; to provide injectable atoms, molecular bonds within O₂ or H₂O must be broken. Second, the injection barrier for the elementary step of injection is only slightly larger than that for bulk site hopping because of commonalities in atomic geometry. Third, the rate-limiting step for transferring an atom from the fluid to the solid comes before the elementary step for injection, and probably entails dissociation of the source molecule. Fourth, a typical treated surface features sites with varying degrees of injection activity. It has been found that surface polarity exerts noticeable but modest effects on injection when either O₂ or H₂O is the source of Oᵢ. For example, the polar O-term (0001̅), polar Zn-term (0001), and nonpolar ZnO (101̅0) orientations yield injection rates and temperature dependences that vary only modestly among one another when either gaseous O₂ or liquid H₂O supplies the injectable O. Reconstruction-influenced differences in local atomic arrangement propagate into the injection barrier Eᵢₙⱼ or the coverage of injectable O. The results suggest that surface-based defect engineering with interstitials may extend to polycrystalline and nanostructured materials that expose many crystallographic orientations.

The lessened chemical coordination at semiconductor surfaces compared to the bulk facilitates creation and destruction of point defects. When the goal is to create (i.e., inject) interstitial atoms, the process is governed by the above-mentioned principles. Most work with semiconducting oxides has focused on oxygen, for which the injecting atoms originate from an O-containing gas or liquid. Many oxides dissociate the precursor H₂O to H and OH even at room temperature. However, further dissociation of OH to atomic O and H entails more difficulty, and the reaction does not occur upon exposure to water vapor. Submersion of the oxide in liquid water enables this deprotonation, however, especially at high pH. It is found that submerged oxide surfaces inject Oᵢ at significant rates even at neutral pH. The O-rich conditions of water exposure evidently provide a driving force sufficient for O to enter the semiconductor, thereby leading to its slight oxidation (e.g., via Oᵢ acting to annihilate Vₒ or react with adventitious H).

A reduction reaction may occur to offset the solid's oxidation. Importantly, oxygen injects only as Oᵢ; isotopic labeling studies with deuterium show that no H atoms from H₂O enter the solid. In the absence of an external circuit, maintaining specimen electroneutrality precludes the sustained release of H⁺ into the liquid. These observations suggest H₂ as the most likely reduction product. No gas bubbles were observed during any of the injection experiments. However, the stoichiometry of the redox reaction, together with the observed injection rates of O, imply production rates of H₂ falling at least an order of magnitude below that needed to saturate the liquid and enable generation of visible bubbles.

It is believed that interstitial injection is a particularly effective strategy for post-synthesis isotopic purification of semiconductor surface regions or layers that already possess substantial enrichment. The disparity among isotopic diffusivities grows as the semiconductor becomes more isotopically pure. Initial material synthesis (e.g., by chemical vapor deposition) may not require special precautions for constituent elements such as O whose natural abundance is already strongly dominated by a single isotope. For applications in quantum spin isolation, for example, the lone stable isotope of oxygen having a nonzero spin is ¹⁷O, whose natural abundance is only 0.04%. For an element like Ti, however, the zero-spin majority isotope (⁴⁸Ti) has a natural abundance of only 74%. The stable isotopes with nonzero spin are ⁴⁷Ti (7.4%) and ⁴⁹Ti, respectively present at 7.4% and 5.4%. Thus, initial material synthesis with isotopically enriched ⁴⁸Ti may be beneficial.

Returning again to FIGS. 1A and 1B, a purified surface region 100 of a semiconductor 106 fabricated according to this method comprises a crystalline metal oxide 108 and an impurity species 110 in the crystalline metal oxide 108, where a concentration of the impurity species 110 as a function of depth follows a curved concentration (or diffusion) profile, as shown for example in FIGS. 2A-2C. The crystalline metal oxide 108 includes a depletion region 118 extending to a first depth and an accumulation region 120 adjacent to the depletion region 118 that extends to a second depth greater than the first depth, where the concentration of the impurity species 110 is lower in the depletion region 118 than in the accumulation region 120. More particularly, the curved concentration profile of the impurity species 110 may include a valley 122 in the depletion region 118 where the concentration of the impurity species 110 reaches a minimum, and a peak 124 in the accumulation region 120 where the concentration of the impurity species 110 reaches a maximum. The minimum concentration (the valley 122) of the impurity species 110 in the depletion region 118 may be less than the maximum concentration (the peak 124) in the accumulation region 120 by a factor of two or more, or a factor of four or more, and in some examples the minimum concentration of the impurity species 110 may be as much as an order of magnitude less than the maximum concentration, even assuming only a single cycle of injection. The extent of purification may depend on the number of available traps to form complexes with the interstitials and the initial impurity concentration. If multiple cycles of injection are carried out, the isotopic or chemical purity may be further increased. For example, the minimum concentration in the depletion region 118 may be as much as two orders of magnitude less than the maximum concentration in the accumulation region 120.

As indicated above, the impurity species 110 may be an isotopic impurity 112 (e.g., an oxygen isotope such as ¹⁸O or a host metal isotope) or a chemical impurity. When the impurity species 110 is an isotopic impurity 112, the concentration of the isotopic impurity 112 in the depletion region 122 may be below a natural abundance of the isotopic impurity 112. In some examples, the concentration of the isotopic impurity 112 in the depletion region 122 may be as much as a factor of three or more below the natural abundance, as discussed above for the example of ¹⁸O. When the impurity species 110 is a chemical impurity, the concentration of the chemical impurity in the depletion region 118 may be significantly reduced compared to a bulk concentration of the chemical impurity in the crystalline metal oxide.

The crystalline metal oxide 108 may comprise a single-crystalline (monocrystalline) metal oxide. In some examples, the crystalline metal oxide may comprise a polycrystalline and/or nanocrystalline metal oxide. In examples in which the crystalline metal oxide is single-crystalline, the crystalline metal oxide may exhibit a crystal lattice structure that is devoid of grain boundaries. Typically, the crystalline metal oxide comprises a semiconducting metal oxide such as TiO₂, ZnO, Ga₂O₃, SrTiO₃, SnO₂, In₂O₃, ITO, WO₃, Cr₂O₃, CuO, Co₂O₃ and/or a perovskite having the general formula ABO₃, where A and B are metal cations such as Ti, Zn, Ga, Sr, Sn, In, W, Cr, Cu and/or Co. In some examples, the crystalline metal oxide may include a dopant such as Al, As, Ce, Er, Fe, Ga, Mg, N, P, Sb and/or Y. Also or alternatively, the crystalline metal oxide may have at least one linear dimension of about 1 micron or less, or about 100 nm or less, and as low as about 1 nm, e.g., the crystalline metal oxide may take the form of a thin film having a thickness of at least about 1 nm and up to about 1 micron, or up to about 100 nm. Alternatively, the crystalline metal oxide may comprise a plurality of nanorods or nanoparticles, each having two or more linear dimensions of about 1 micron or less, or about 100 nm or less, and as small as about 1 nm. In such an example, the crystalline metal oxide is preferably at least partially sintered to ensure electrical contact between adjacent nanorods or nanoparticles.

As indicated above, the injectable atomic species (e.g., the atomic oxygen or metal cations) may require an atomically clean surface for adsorption and subsequent injection. Accordingly, the purified surface region 100 of the semiconductor 106 may include a treated surface 106a, that is, a surface prepared as described below to be substantially poison-free (contaminant-free). Suitably prepared surfaces offer a means for manipulating defect populations, in particular for semiconducting metal oxides where defects may significantly influence technologically relevant material properties. The removal of strongly bonded adsorbates, such as carbon and/or sulfur on TiO₂ or ZnO, may be critical. Even at coverages well below one monolayer, such adsorbates may prove capable of poisoning the kinetic pathways responsible for defect exchange between the surface and bulk. Other adsorbates, such as water, atomic hydrogen, and sodium and/or chlorine from dissolved NaCl, may adsorb onto the surface but may not act as poisons (e.g., by interfering with the isotopic profiles). Ideally, the treated surface includes a concentration of contaminants of 0.01 ML (about 1% of a monolayer) or less. In some cases, the concentration of contaminants may be about 0.005 ML or less, or as low as about 0.001 ML. The treated surface may comprise a polar or non-polar surface, where, in the former case, the polar surface may be cation-or anion-terminated.

Methods to prepare the treated surface 106a have been developed. In one example, the method includes degreasing a surface of the crystalline metal oxide, followed by wet etching of the surface and/or vacuum annealing of the crystalline metal oxide. The degreasing may comprise exposing the surface to acetone, isopropyl alcohol, ethanol and/or methanol by, for example, immersion in an ultrasonic bath. Vacuum annealing may entail heating the surface at a temperature in a range from about 400° C. to about 550° C. at an oxygen pressure P_{O2} in a range from about 1×10⁻⁶ Torr to about 1×10⁻⁴ Torr. Typically, the heating is carried out from 30 minutes to 24 hours. The wet etching, when employed to prepare the treated surface, may comprise exposing the surface to hydrogen peroxide (H₂O₂) and/or ammonium hydroxide (NH₄OH) under suitable conditions, as described for for example for ZnO and TiO₂ in U.S. Patent Application Publication No. 2022/0231171, published on Jul. 21, 2022, which is hereby incorporated by reference in its entirety.

The experimental work described below demonstrates fractionation for rutile TiO₂ single crystals using liquid pH as a tool to modulate the injection flux, as well as other chemical and physical characteristics of the near-surface bulk. Isotopic self-diffusion experiments are used to monitor defect behavior, wherein cleaned and etched oxide specimens are submerged in water containing excess ¹⁸O as a label. Oxygen enters the solid as Oᵢ and undergoes interstitialcy-mediated diffusion. Depth profiles of ¹⁸O are measured afterward by secondary ion mass spectrometry (SIMS).

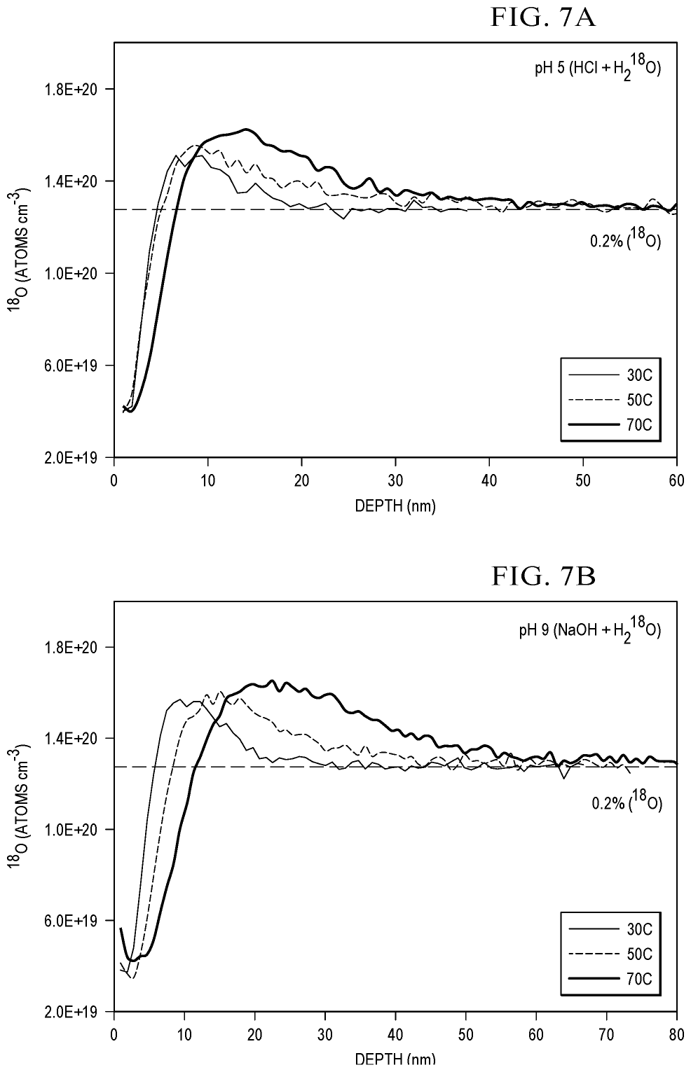

FIGS. 7A and 7B show exemplary ¹⁸O concentration profiles after 1-hour water exposures at pH values of 5 and 9—both at several temperatures. A striking feature, visible at both pH levels, is the large “valley” in label concentration near the surface that is up to about 10 nm wide. Counterintuitively, this isotopically depleted valley emerges despite the enrichment of the liquid water to 10% ¹⁸O. Depletion of label within the valley region drives the ¹⁸O concentration down to about a factor of three below the natural abundance level. The ¹⁸O lost from the valley builds up as a peak lying deeper in the bulk. The amount of ¹⁸O contained within the peak exceeds the amount depleted from the valley, with the difference equaling the total amount of injected ¹⁸O.

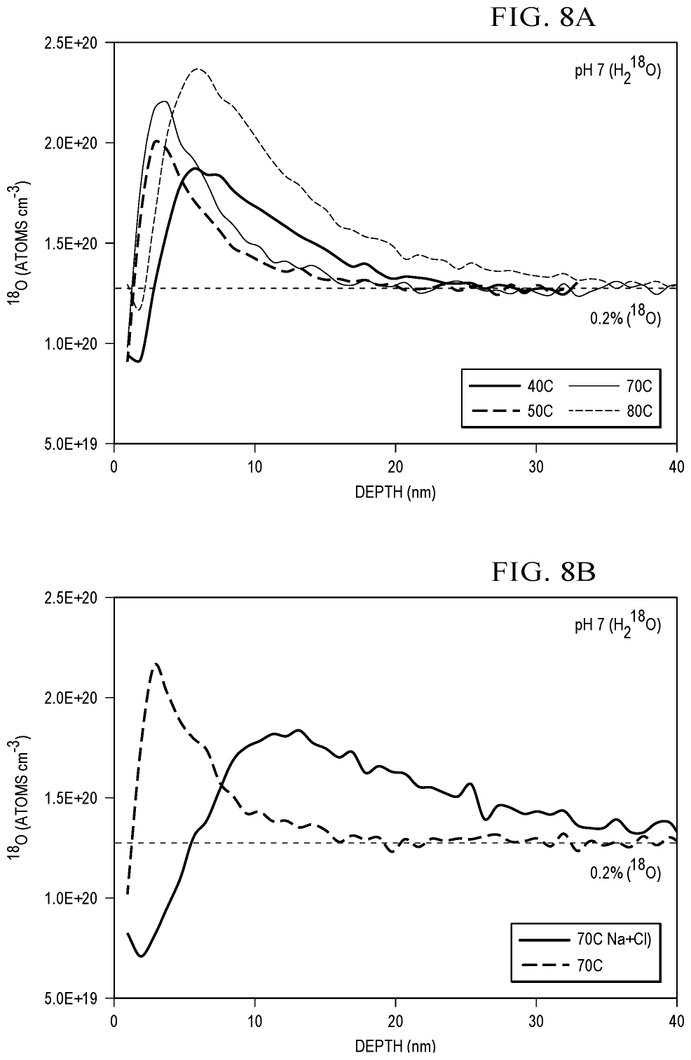

FIGS. 8A and 8B show exemplary ¹⁸O concentration profiles after immersion in water at various temperatures for 1 hour at pH 7. At pH 7, the valley is much narrower and less prominent than at pH 5 or 9. However, adding both NaOH and HCl in concentrations equivalent to those at pH 5 or 9 (thereby making a salt solution of NaCl) strengthens fractionation to a magnitude lying between pH 7 and either 5 or 9.

Profile shapes sometimes exhibited noticeable variability in the near-surface region, especially at pH 7. X-ray photoelectron spectroscopy (XPS) combined with SIMS performed at several locations on single specimens, as well as among specimens, showed variable adsorption of adventitious impurities—especially carbon-containing species. Such species can act not only to poison injection sites but also to influence buildup of electrical charge on the surface. The resulting drift forces on charged interstitials can strongly affect profile shape in the space charge layer near the surface. Such adventitious adsorption proved difficult to control and often varied across the surface of a single specimen. Nevertheless, the primary trends described herein remained robust even with such variations.

Some of the profiles in FIGS. 7A-8B exhibit slight upturns in ¹⁸O concentration within the first nanometer of the surface. Profile shapes in this extremely shallow region suffer from distortions due to various well-known SIMS artifacts. However, the upturns occurred more prominently and commonly at pH 7 than for pH 5 or 9, which suggests that the upturn represents a qualitatively accurate description of the actual profiles.

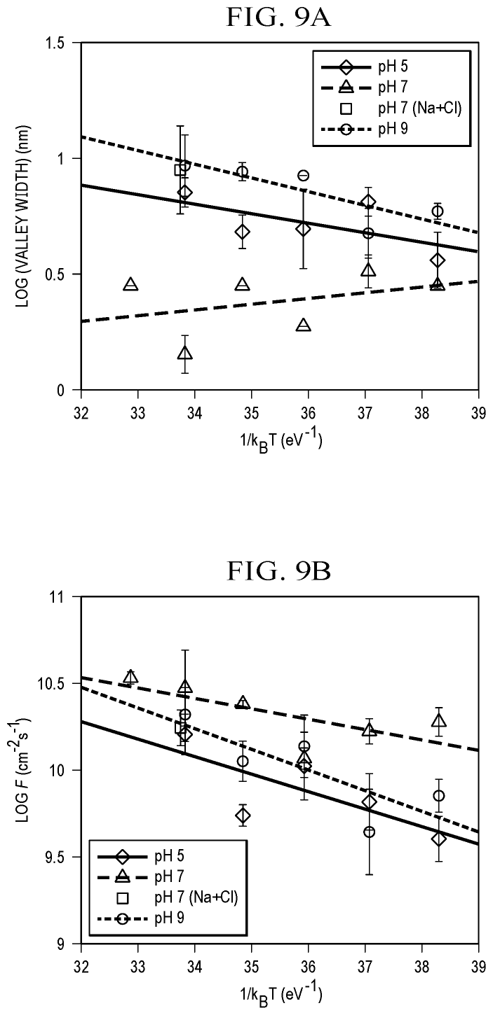

FIG. 9A shows Arrhenius plots of the valley width, defined as the depth from the surface at which the ¹⁸O concentration returns to the natural abundance level, as a function of pH. The width increases with temperature from 3 to nearly 10 nm at pH 5 or 9, but actually decreases from 3 to 1 nm for pH 7. The effective activation energies for these changes are small—on the order of 0.1 eV or less, as can be seen in Table 1. FIG. 9B shows the net injection flux of F₁₈ of ¹⁸O atoms in Arrhenius form for all three pH levels. Since the water is 10% isotopically pure in ¹⁸O, the total flux F of Oᵢ (all isotopes) may be computed as a factor of 10 greater than F₁₈, assuming that Oᵢ injects with an isotopic makeup equal to that of the water. Although F₁₈ at pH 5 and 9 (and with NaCl) is generally lower than that at pH 7, the activation energy of F₁₈ is slightly higher.

TABLE 1
Activation Energies for F, Valley Width, Penetration Depth, and λ

| | Activation energy (eV) | | |
|---|---|---|---|
| Parameter | pH 5 | pH 7 | pH 9 |
| F (cm⁻² s⁻¹) | 0.23 ± 0.11 | 0.13 ± 0.06 | 0.27 ± 0.11 |
| Valley width (nm) | 0.09 ± 0.06 | −0.05 ± 0.02 | 0.13 ± 0.05 |
| Penetration depth (nm) | 0.16 ± 0.09 | 0.08 ± 0.04 | 0.20 ± 0.07 |
| λ (nm) | 0.12 ± 0.09 | 0.06 ± 0.06 | 0.26 ± 0.11 |

The deeper portions of the profiles were quantified using two metrics: penetration depth and mean diffusion length (λ). Both parameters were computed as described below. For pH 5, the penetration depth increases with temperature from 10 to 50 nm, with λ increasing from 5 to 8 nm between 30-70° C. For pH 9, the behavior is similar, with slightly larger values of 10-70 nm for penetration depth and 4-17 nm for λ. These metrics show intermediate behavior at pH 7, with a range of 15-60 nm for the penetration depth and 5-11 nm for λ. Table 1 compares the activation energies for these metrics, which are all modest (0.2 eV or less) but are consistently lowest at pH 7.

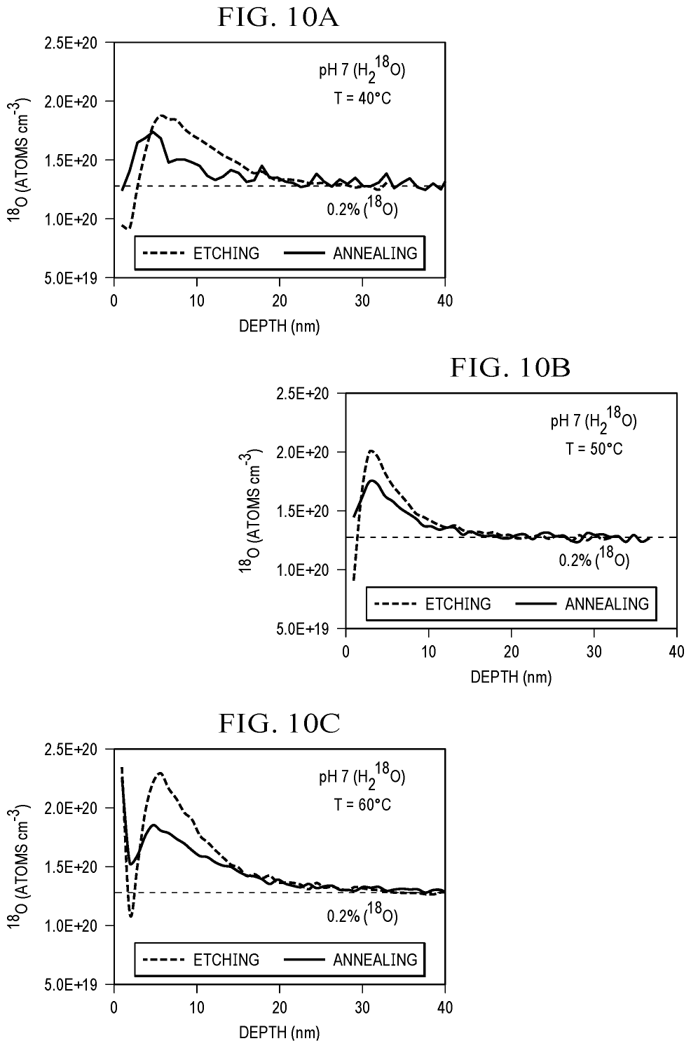

FIGS. 10A-10C show various examples of ¹⁸O concentration profiles at pH 7—comparing specimens initially exposed to room-temperature wet etching vs. high-temperature annealing in O₂. Annealing eliminates some of the trapping sites for Oᵢ that exist before self-diffusion starts. The near-surface isotopic fractionation is consistently larger for the room temperature preparation.

A mechanism involving interstitialcy-mediated diffusion as described above can explain these effects based on hopping statistics combined with low label concentrations and steep interstitial gradients. An interstitialcy mechanism entails frequent exchange between atoms in the defect and on lattice sites. The steep gradients arise partly from the low bond coordination of O atoms adsorbed on clean metal oxide surfaces, which facilitates creation of Oᵢ with barriers below roughly 1 eV. These injection barriers, combined with even lower bulk hopping barriers, enable clean oxide surfaces exposed to liquid water to inject Oᵢ at substantial rates even near room temperature. Because the equilibrium concentration of Oᵢ in this regime is vanishingly small, fast injection initially creates a sharp interstitial gradient. ¹⁸O liberated as Oᵢ from the lattice is pulled deeper into the bulk by this strong gradient. Moreover, the isotopic disparity in diffusivity enables ¹⁶Oᵢ; to race far ahead of ¹⁸Oᵢ, which biases the isotopic composition of interstitials at the leading edge of the interstitial diffusion front toward ¹⁶O. These combined effects enable ¹⁶O to replace much of the ¹⁸O present originally in the lattice—pushing the displaced ¹⁸O deeper into the bulk and creating a valley-and-peak isotopic profile shape. The net effect loosely resembles that of a snowplow acting on ¹⁸O.

The profiles in FIGS. 10A-10C demonstrate the importance of the steepness of the gradient in Oᵢ concentration. In single-crystal TiO₂ whose treated surface has been cleaned by wet etching at room temperature, many traps for Oᵢ remain in the bulk, including O vacancies (Vₒ) and extrinsic elements such as H. Vₒ reacts with Oᵢ by mutual annihilation, while interstitial H reacts to form Oᵢ-Hᵢ complexes. By contrast, high-temperature annealing in O₂ not only cleans the surface, but also injects Oᵢ. This injection eliminates Vₒ down to depth of several hundred nanometers, and may also result in some volatilization of hydrogen. Thus, fewer traps exist to react with Oᵢ during subsequent water exposure. The lessened trapping enables the concentration profile of Oᵢ to smoothen more rapidly, thereby leading to Oᵢ gradients that are less sharp. Accordingly, annealed crystals exhibit lessened isotopic fractionation, leading to less pronounced valleys in FIGS. 10A-10C.

This physical picture relies upon an interstitialcy mechanism, which, as discussed above, is distinguished from an interstitial mechanism where a single interstitial atom diffuses many lattice spacings before becoming trapped or kicking into the lattice. The latter mechanism is not able to produce the large isotopic disparity in diffusivity strong fractionation requires. However, as noted above, it is believed that an analogous effect operates in modified form for interstitialcy diffusion of extrinsic chemical elements and for interstitial diffusion of either isotopes or extrinsic chemical elements where the mean diffusion length before kick-in to the lattice is short (e.g., a few lattice spacings). A more refined description of interstitialcy-mediated fractionation would allow for slight isotopic differences in hopping rates due to different vibrational frequencies and zero point energies. However, these effects represent only minor perturbations on the primary governing factors—hopping statistics and sharp gradients.

The slight upturn in ¹⁸O concentration next to the surface observed for some specimens presumably corresponds to label atoms originating from water (distinguished from those already present in the lattice) that have propagated far enough to become barely visible in SIMS.

For a water molecule to supply injectable oxygen, loss of both hydrogen atoms must occur—a process affected by pH. Solution acidity or basicity may affect the details of the profile shapes through several mechanisms, including the Oᵢ trapping efficiency, the net injection flux, and changes in the Fermi energy (E_{F}) at the surface. Sophisticated process simulators akin to those available for ion-implantation in microelectronic devices may be required to model these effects, but the following paragraphs enumerate some of them.

Some defect complexes containing Oᵢ exist in multiple charge states, meaning their concentration becomes spatially dependent if excess charge on the surface creates a space charge layer (SCL). Acid-base reactions with water induce a net charge on the TiO₂ surface except at the isoelectric point, which is equivalent to the point of zero charge (PZC) if no specific adsorption occurs. For rutile TiO₂ this point varies with incorporated impurities and roughness, but averages about pH 5, with a standard deviation is about 0.8. Thus, excess negative charge resides at the surface over most or all of the pH range examined here, giving rise to a depletion-type SCL in the n-type rutile. Depending upon the magnitude of the band bending and the ionization levels of the relevant trapping complexes, spatial variations could exist in the concentrations of trapping sites. Indeed, annihilation of donor Vₒ and formation of such complexes may change the background donor concentration throughout the solid down to the penetration depth of Oᵢ. This penetration depth varies with time, leading to a time evolution in the spatial variation of trap concentration.

F represents the mathematical difference between the rates of injection and annihilation, and depends upon pH through several mechanisms. First, the coverage of OH (i.e., the singly deprotonated precursor to injectable O) varies with pH, with complete deprotonation occurring only for pH>13. Second, key rate constants change with pH. These constants include the activation energies and pre-exponential factors for both injection and re-incorporation of back-diffusing Oᵢ at the surface. The liquid's pH determines the amount of negatively charged OH that adsorbs, which in turn affects E_{F} at the surface. The activation energy for Oᵢ injection and re-incorporation vary with E_{F} due to changes in charge state of the chemical intermediates involved in injection. The pre-exponential factors almost certainly vary as well, although those numbers remain unknown. Third, the SCL that attends band bending induces a drift component to the motion of Oᵢ, which exists in the −2 charge state in bulk rutile above a E_{F} of about 0.9 eV. The electric field repels negatively charged mobile defects such as Oᵢ from the surface, thereby impeding re-incorporation of interstitials.

E_{F} itself may change over time. One possible cause is slow adsorption of adventitious impurities including various carbon-containing species. These species not only poison injection sites but also may enhance or inhibit acid-base reactions between the surface and water that lead to surface charge buildup. Such adventitious adsorption is difficult to control and can vary across the surface of a single specimen. Such effects probably contribute to the confidence intervals shown in FIGS. 9A and 9B. A second possible cause involves excess charge buildup over time. A relationship between pH and PZC for d⁰ oxides such as TiO₂ has been proposed only in the past decade, and a relationship between E_{F} and pH under conditions far from the PZC remains unknown. Ions of opposite charge from the electrolyte may partly compensate charge buildup from acid-base reactions, as suggested by the NaCl data of FIG. 8B. In the absence of applied bias potential, it remains an unsolved problem in surface science to compute self-consistently the net charge accumulation resulting from acid-base interactions in the presence of partial compensation by both ion adsorption from the electrolyte and SCL formation in the solid. For thin films and nanostructures possessing limited bulk volume, E_{F} at the surface will vary with time because neutralization of charged traps by Oᵢ will progressively diminish the bulk's ability compensate excess charge at the interface.

The data presented here demonstrate isotopic purification of O by about a factor of three from natural abundance levels in a region up to 10 nm wide. Mesoscale simulation models may be beneficial for predicting ultimate limitations on the width of the isotopically purified region, the degree of purification possible during a single exposure, and the dependence of these parameters on conditions such as the injected flux, isotopic purity of the water, temperature, electrolyte concentration, and other factors.

In conclusion, through isotopic self-diffusion measurements of oxygen in rutile TiO₂ single crystals immersed in water, fractionation of ¹⁸O by a factor of three below natural abundance has been demonstrated in a near-surface region up to 10 nm wide. Slightly acidic and slightly basic liquid solutions both enhance the fractionation. Isotopic purification of ¹⁶O near the surface is governed by the statistics of interstitialcy-mediated diffusion combined with steep chemical gradients of O interstitials originating from the submerged surface. As explained above, there is no reason to believe the fundamental physical picture is restricted only to oxygen or TiO₂. As an approach to post-synthesis isotopic purification, higher purities are likely to be reached through repeated pause-and-inject cycles. Interstitialcy diffusion is common among elements in both single-component and compound semiconductors, suggesting that this approach to isotopic purification may find extensive use as methods for interstitial injection from surfaces continue to develop.

### Materials and Methods

Protocols for the isotopic self-diffusion experiments are summarized here. Single-crystals specimens of TiO₂ were immersed in ¹⁸O-labeled water (10 atomic % ¹⁸O, Sigma-Aldrich) for 1 hour at constant temperatures ranging between 30 and 80° C. with different values of pH. Adding appropriate amounts of dissolved and diluted reagent grade NaOH (Fisher Scientific) or diluted 30% HCl (VWR Chemicals) enabled the variation of pH. Simultaneous addition of both NaOH and HCl enabled examination of the effects of dissolved NaCl at pH 7, with ion concentrations set to equal those characteristic of pH 5 (for CI) and pH 9 (for Na).

Rutile TiO₂(110) specimens (MTI Corporation) of dimensions 5 mm×5 mm×0.5 mm were prepared to have treated surfaces by degreasing with successive 10 min ultrasonic baths in acetone, isopropanol, ethanol, and methanol, followed by wet etching (1:2 of 30% NH₄OH: H₂O) at room temperature for 40 min in order to remove foreign-element poisons that inhibit Oᵢ injection and smoothen the rms surface roughness from 0.23 to 0.14 nm.

Some specimens underwent high-temperature annealing in low-pressure natural-abundance O₂ gas (99.995%) for 4 hour in an ultrahigh vacuum-compatible apparatus. These specimens were first degreased by successive 10 min ultrasonic baths in reagent-grade acetone, isopropanol, ethanol, and methanol. Annealing followed in 5×10⁻⁶ Torr of O₂ at 450° C.

After self-diffusion, ¹⁸O concentration profiles were measured by ex-situ time of flight SIMS (PHI-TRIFT III). A 3 keV Cs ion beam source was used. For calibration, the ¹⁸O concentrations were normalized by the known natural abundance ¹⁸O concentration (0.2%) measured with as-received TiO₂ specimens. In some specimens, X-ray photoelectron spectroscopy (XPS) was employed to determine surface elemental composition.

Several metrics were employed to quantify and interpret the profiles. The amount of ¹⁸O entering the solid was obtained by direct integration of the profiles, including both the valley and peak. Division of this amount by the time of exposure yielded the time-averaged net injection flux F₁₈ of ¹⁸O. The valley width was defined as the depth within the solid between the valley and peak at which the ¹⁸O concentration crossed the natural abundance level (0.2%). The deep-bulk profiles past the peak were quantified by two other metrics.

One metric, the mean diffusion length λ, was computed according to a procedure described elsewhere ⁴ using the expression

$$ln ( \frac{C - {C}_{0}}{{C}_{0}^{T} - {C}_{0}} ) = ln ( \frac{{F}_{18}}{λ [ {C}_{O}^{T} - {C}_{O} ]} t ) - \frac{x}{λ} , \qquad ( 1 )$$

where C denotes the measured concentration of ¹⁸O, C₀ is the natural abundance concentration of ¹⁸O, C_{O}^{T} is the total concentration of the lattice sites capable of exchanging with Oᵢ, t is the diffusion time and x denotes the spatial coordinate with x=0 set at the surface. The profile slope yields the mean diffusion length (λ), and the intercept nominally yields the net injection flux (F₁₈). However, the physical model underlying Eq. (1) does not allow for the valley observed in the present work, so F₁₈ was computed by integration as described above. Fitting of Eq. (1) to the present profiles beyond the peak did yield straight lines, however, with a decay length corresponding to λ. Consequently, λ is reported as a phenomenological parameter, not necessarily with the physical significance presupposed in the derivation of Eq. (1).

Because of the uncertain physical significance of λ, a second deep-bulk parameter—the ¹⁸O penetration depth, which was defined as the depth beyond the peak at which the ¹⁸O concentration reached 1.30×10²⁰ cm⁻³, was also examined. This concentration is slightly higher than the natural abundance baseline concentration of ¹⁸O (1.27×10²⁰ cm⁻³), and enables the precise (although somewhat arbitrary) definition of the “end” of a profile whose shape declines asymptotically to the baseline.

The subject matter of this disclosure may also relate to the following aspects:

A first aspect relates to a purified surface region comprising: a semiconductor having a treated surface and comprising a crystalline metal oxide containing an impurity species, the crystalline metal oxide comprising: a depletion region extending to a first depth from the treated surface; an accumulation region adjacent to the depletion region and extending to a second depth greater than the first depth, wherein a concentration of the impurity species is lower in the depletion region than in the accumulation region.

A second aspect relates to the purified surface region of the first aspect, wherein the concentration of the impurity species in the crystalline metal oxide follows a curved concentration profile as a function of depth.

A third aspect relates to the purified surface region of the first or second aspect, wherein the curved concentration profile comprises: a valley in the depletion region where the concentration of the impurity species is at a minimum; and a peak in the accumulation region where the concentration of the impurity species is at a maximum.

A fourth aspect relates to the purified surface region of any preceding aspect, wherein the treated surface is an atomically-clean surface including a concentration of contaminants of about 0.01 monolayer (ML) or less, and/or as low as about 0.001 ML.

A fifth aspect relates to the purified surface region of any preceding aspect, wherein the impurity species comprises an isotopic impurity or a chemical impurity.

A sixth aspect relates to the purified surface region of the fifth aspect, wherein the isotopic impurity comprises an oxygen isotope or a host metal isotope.

A seventh aspect relates to the purified surface region of the fifth or sixth aspect, wherein the concentration of the isotopic impurity in the depletion region is below a natural abundance of the isotopic impurity.

An eighth aspect relates to the purified surface region of the seventh aspect, wherein the concentration is a factor of three or more below the natural abundance.

A ninth aspect relates to the purified surface region of the fifth aspect, wherein the concentration of the chemical impurity in the depletion region is reduced compared to a bulk concentration of the chemical impurity.

A tenth aspect relates to the purified surface region of any preceding aspect, wherein the impurity species diffuses by an interstitialcy mechanism.

An eleventh aspect relates to the purified surface region of any preceding aspect, wherein interstitials are a majority point defect in the crystalline metal oxide.

A twelfth aspect relates to the purified surface region of any preceding aspect, wherein the crystalline metal oxide comprises a single crystalline metal oxide.

A thirteenth aspect relates to the purified surface region of any preceding aspect, wherein the crystalline metal oxide comprises a polycrystalline and/or nanocrystalline metal oxide.

A fourteenth aspect relates to the purified surface region of any preceding aspect, wherein the first depth to which the depletion region extends is from about 5 nm to about 30 nm.

A fifteenth aspect relates to the purified surface region of any preceding aspect, wherein the second depth to which the accumulation region extends is from about 20 nm to about 400 nm.

A sixteenth aspect relates to an electronic component comprising the purified surface region of any preceding aspect and being configured for thermal management, quantum computing, sensing, and/or light detection.

A seventeenth aspect relates to a near-surface purification method for a semiconductor, the purification method comprising: injecting atomic oxygen and/or metal cations into a treated surface of a semiconductor comprising a crystalline metal oxide and an impurity species, the atomic oxygen or metal cations moving through the crystalline metal oxide as interstitials, whereby the impurity species are depleted from a depletion region of the crystalline metal oxide and diffused deeper into the crystalline metal oxide to an accumulation region farther from the treated surface than the depletion region.

An eighteenth aspect relates to the purification method of the seventeenth aspect, wherein injecting the atomic oxygen and/or the metal cations into the crystalline metal oxide comprises: submerging the treated surface in water or an aqueous solution comprising water at a temperature and pressure sufficient to maintain the water in a liquid phase, whereby a portion of the water adsorbs onto the treated surface and dissociates into the atomic oxygen and hydrogen.

A nineteenth aspect relates to the purification method of the eighteenth aspect, wherein the aqueous solution contains a soluble compound comprising the metal cations, and wherein, during the submerging, the metal cations adsorb onto the treated surface.

A twentieth aspect relates to the purification method of the eighteenth or nineteenth aspect, further comprising, while the treated surface is submerged, applying a bias voltage to the treated surface.

A twenty-first aspect relates to the purification method of the twentieth aspect, wherein the bias voltage is in a range from −0.6 V to +0.6 V vs Ag/AgCl.

A twenty-second aspect relates to the purification method of any preceding aspect, wherein the aqueous solution includes a metal salt.

A twenty-third aspect relates to the purification method of any preceding aspect, wherein the aqueous solution includes an acid and/or base.

A twenty-fourth aspect relates to the purification method of any preceding aspect, wherein the aqueous solution has a pH in a range from 2 to 10.

A twenty-fifth aspect relates to the purification method of any preceding aspect, further comprising exposing the treated surface to above-bandgap radiation, the above-bandgap radiation having a photon energy at or above a bandgap of the crystalline metal oxide.

A twenty-sixth aspect relates to the purification method of any preceding aspect, wherein the impurity species comprises an isotopic impurity or a chemical impurity.

A twenty-seventh aspect relates to the purification method of the twenty-sixth aspect, wherein the isotopic impurity comprises an oxygen isotope or a host metal isotope.

A twenty-eighth aspect relates to the purification method of the twenty-sixth or twenty-seventh aspect, wherein the concentration of the isotopic impurity in the depletion region is below a natural abundance of the isotopic impurity.

A twenty-ninth aspect relates to the purification method of the twenty-eighth aspect, wherein the concentration is a factor of three or more below the natural abundance.

A thirtieth aspect relates to the purification method of the twenty-sixth aspect, wherein the concentration of the chemical impurity in the depletion region is reduced compared to a bulk concentration of the chemical impurity.

A thirty-first aspect relates to the purification method of any preceding aspect, wherein the atomic oxygen or metal cations are enriched with the isotopic impurity.

A thirty-second aspect relates to the purification method of any preceding aspect, wherein multiple cycles of the injection are carried out to increase isotopic or chemical purity.

A thirty-third aspect relates to the purification method of any preceding aspect, wherein the injection takes place at a temperature of less than 100° C. and at atmospheric pressure.

A thirty-fourth aspect relates to the purification method of the thirty-third aspect, wherein the temperature is in a range from 30° C. to 80° C.

A thirty-fifth aspect relates to the purification method of any preceding aspect, wherein the injection takes place at a temperature of at least 100° C. and at a pressure in a range from greater than about 100 kPa to about 10 GPa.

A thirty-sixth aspect relates to the purification method of any preceding aspect, further comprising, prior to the injection, preparing the treated surface, the preparing comprising: degreasing a surface of the crystalline metal oxide, followed by wet etching of the surface and/or vacuum annealing of the crystalline metal oxide.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

While various embodiments have been described, it will be apparent to those of ordinary skill in the art that many more embodiments and implementations are possible. Accordingly, the embodiments described herein are examples, not the only possible embodiments and implementations.

In addition to the features mentioned in each of the independent aspects enumerated above, some examples may show, alone or in combination, the optional features mentioned in the dependent aspects and/or as disclosed in the description above and shown in the figures.

1. A purified surface region comprising:
a semiconductor having a treated surface and comprising a crystalline metal oxide containing an impurity species, the crystalline metal oxide comprising:
a depletion region extending to a first depth from the treated surface;
an accumulation region adjacent to the depletion region and extending to a second depth greater than the first depth;
wherein a concentration of the impurity species is lower in the depletion region than in the accumulation region.

2. The purified surface region of claim 1, wherein the concentration of the impurity species in the crystalline metal oxide follows a curved concentration profile as a function of depth.

3. The purified surface region of claim 1, wherein the curved concentration profile comprises:
a valley in the depletion region where the concentration of the impurity species is at a minimum; and
a peak in the accumulation region where the concentration of the impurity species is at a maximum.

4. The purified surface region of claim 1, wherein the treated surface is an atomically-clean surface including a concentration of contaminants of about 0.01 monolayer (ML) or less.

5. The purified surface region of claim 1, wherein the impurity species comprises an isotopic impurity or a chemical impurity.

6. The purified surface region of claim 5, wherein the concentration of the isotopic impurity in the depletion region is below a natural abundance of the isotopic impurity.

7. The purified surface region of claim 6, wherein the concentration is a factor of three or more below the natural abundance.

8. The purified surface region of claim 5, wherein the concentration of the chemical impurity in the depletion region is reduced compared to a bulk concentration of the chemical impurity.

9. The purified surface region of claim 1, wherein the first depth to which the depletion region extends is from about 5 nm to about 30 nm.

10. The purified surface region of claim 1, wherein the second depth to which the accumulation region extends is from about 20 nm to about 400 nm.

11. An electronic component comprising the purified surface region of claim 1 and being configured for thermal management, quantum computing, sensing, and/or light detection.

12. A near-surface purification method for a semiconductor, the purification method comprising:
injecting atomic oxygen and/or metal cations into a treated surface of a semiconductor comprising a crystalline metal oxide and an impurity species, the atomic oxygen or metal cations moving through the crystalline metal oxide as interstitials,
whereby the impurity species are depleted from a depletion region of the crystalline metal oxide and diffused deeper into the crystalline metal oxide to an accumulation region farther from the treated surface than the depletion region.

13. The purification method of claim 12, wherein injecting the atomic oxygen and/or the metal cations into the crystalline metal oxide comprises:
submerging the treated surface in water or an aqueous solution comprising water at a temperature and pressure sufficient to maintain the water in a liquid phase, whereby a portion of the water adsorbs onto the treated surface and dissociates into the atomic oxygen and hydrogen.

14. The purification method of claim 13, wherein the aqueous solution contains a soluble compound comprising the metal cations, and
wherein, during the submerging, the metal cations adsorb onto the treated surface.

15. The purification method of claim 13, further comprising, while the treated surface is submerged, applying a bias voltage to the treated surface.

16. The purification method of claim 15, wherein the bias voltage is in a range from −0.6 V to +0.6 V vs Ag/AgCl.

17. The purification method of claim 13, wherein the aqueous solution includes a metal salt, and/or
wherein the aqueous solution includes an acid and/or base.

18. The purification method of claim 12, further comprising exposing the treated surface to above-bandgap radiation, the above-bandgap radiation having a photon energy at or above a bandgap of the crystalline metal oxide.

19. The purification method of claim 12, wherein the impurity species comprises an isotopic impurity or a chemical impurity.

20. The purification method of claim 12, wherein multiple cycles of the injection are carried out to increase isotopic or chemical purity.
